(19) United States
(12) Patent Application Publication
(10) Pub. No.: US 2013/0180451 A1
(43) Pub. Date: Jul. 18, 2013

(54) SUBSTRATE TREATMENT SYSTEM

(71) Applicant: Nobuo Horiuchi, Otsu-shi (JP)

(72) Inventor: Nobuo Horiuchi, Otsu-shi (JP)

(21) Appl. No.: 13/825,957

(22) PCT Filed: Jul. 29, 2011
(86) PCT No.: PCT/JP2011/067411

§ 371 Date: Mar. 25, 2013

(30) Foreign Application Priority Data
Sep. 27, 2010 (JP) 2010-215801

(51) Int. Cl. C23C 16/455

(52) U.S. Cl. CPC C23C 16/45557
USPC 118/715

(57) ABSTRACT

The present invention addresses the problem of providing a substrate treatment system for making it possible to keep the inside of a chamber at a stable pressure, even when a variance occurs in the supply flow rate of an inert gas, and for making it possible to increase the supply flow rate of the inert gas and reduce the duration of time needed to fill with the inert gas during an initial operation. The present invention adopts a configuration provided with: a substrate treatment section for carrying out a predetermined treatment on the substrate; a chamber for accommodating the substrate treatment section in a sealed state; a gas supply unit for supplying an inert gas to inside the chamber; and a gas exhaust unit for discharging the gas inside the chamber; the supply flow rate of the inert gas of the gas supply unit and the exhaust flow rate of the gas exhaust unit being adjusted so that the pressure inside the chamber reaches a chamber setting pressure higher than the pressure outside the chamber.

### CROSS-REFERENCE TO RELATED APPLICATION

This national phase patent application claims priority to Japanese Patent Application No. ______. The entire disclosure of Japanese Patent Application No. is hereby incorporated herewith by reference.

### BACKGROUND

1. Technical Field

The present invention relates to a substrate processing system for carrying out a predetermined processing on a substrate, wherein the substrate is treated in a state where a chamber has been filled with an inert gas.

2. Background Art

In general, the manufacture of semiconductor apparatuses, masks, and the like involves the use of a variety of different substrate processing systems for carrying out a predetermined processing on a substrate, such as a coating apparatus for coating a substrate with a resist solution, a substrate transport apparatus, or a drying apparatus for drying a coated film that is on a substrate. Typically, because oxidation is very undesirable for a coated film on a substrate formed with a resist solution, these apparatuses are arranged within a simple closed chamber, and the predetermined processing is carried out within the chamber.

More specifically, as is illustrated in Patent Reference 1, a coating apparatus is arranged within a chamber, and a supply port for supplying an inert gas to the chamber and an exhaust port for discharging the atmosphere within the chamber are provided to the chamber. During operation of the apparatus, air is discharged from the exhaust port while an inert gas is also being supplied to the chamber from the supply port, to thereby lower the oxygen concentration inside the chamber as much as possible; a resist solution is then ejected onto the substrate, and a coated film is formed. That is, the dimensions of the supply port and the exhaust port in the chamber are designed so that the amount of air discharged from the exhaust port is less than the amount of inert gas supplied from the supply port; when the inert gas is supplied, the oxygen inside the chamber is gradually replaced with the newly supplied inert gas (is filled with inert gas). The chamber is kept at a somewhat elevated pressure, which prevents oxygen in the air from coming into the chamber. As such, the oxygen concentration in the chamber can be kept below a predetermined oxygen concentration, and the coated film that is formed on the substrate can be prevented from being oxidized.

### PRIOR ART REFERENCES

### Patent References

Patent Reference 1: Japanese Laid-open Patent Publication 2005-211734

### SUMMARY

### Problems to be Solved by the Invention

However, a problem with the substrate processing system described above has emerged in that the oxygen concentration in the chamber cannot be suppressed to a predetermined oxygen concentration. That is, the supply sources for the inert gas are set differently from one factory to another, and are shared by a variety of different apparatuses. For this reason, in the substrate processing system described above in which the flow rate is adjusted with the dimensions of the supply port and the exhaust port, in a case where the supply pressure falls temporarily due to the circumstances of use of the inert gas, then the supply flow rate for the inert gas being supplied from the supply power falls below the exhaust flow rate of air being discharged from the exhaust port. As a result, a problem has emerged in that the inside of the chamber reaches atmospheric pressure or lower, and this makes it more likely that the oxygen in the air will come into the chamber and causes a concern in that the oxygen concentration in the chamber might be elevated.

Also, in a case where the pressure of the supply source is sufficient, there is a desire to increase the supply flow rate of the inert gas and reduce the duration of time needed to fill the chamber with inert gas at the time of an initial operation for supplying the inert gas to the chamber. However, when the supply flow rate of the inert gas is increased, because the exhaust flow rate of the exhaust port is substantially constant, the pressure in the chamber is excessively elevated, and a problem has emerged in that there is a concern that the inert gas could leak from the chamber or the chamber itself could be destroyed.

The present invention has been contrived in view of the foregoing problems, and an objective thereof is to provide a substrate processing system for making it possible to keep the inside of a chamber at a stable pressure, even when a variance occurs in the supply flow rate of an inert gas, and for making it possible to increase the supply flow rate of the inert gas and reduce the duration of time needed to fill with the inert gas during an initial operation.

### Means for Solving the Problems

In order to resolve the foregoing problems, the substrate processing system of the present invention is characterized in being provided with: a stage atop which a substrate is placed; a substrate processing section for carrying out a predetermined processing on the substrate having been placed on the stage; a chamber for covering the stage and the substrate processing section in a sealed state; a gas supply unit for supplying an inert gas to inside the chamber; and a gas exhaust unit for discharging the gas inside the chamber; the supply flow rate of the inert gas of the gas supply unit and the exhaust flow rate of the gas exhaust unit being adjusted on the basis of the pressure inside the chamber so that the pressure inside the chamber reaches a chamber setting pressure value higher than the pressure outside the chamber.

According to the foregoing substrate processing system, the pressure inside the chamber can be stably maintained at the chamber setting pressure, because the supply flow rate of the inert gas of the gas supply unit and the exhaust flow rate of the gas exhaust unit are adjusted on the basis of the pressure inside the chamber. That is, even when a variance occurs in the supply flow rate of the inert gas, the inside of the chamber is maintained at a constant chamber setting pressure, due to the fact that the exhaust flow rate is adjusted in accordance with the supply flow rate. As such, having the pressure inside the chamber be higher than the pressure outside the chamber makes it possible to curb the entry of oxygen into the chamber from outside the chamber, and makes it possible to curb an elevation in the oxygen concentration inside the chamber. Additionally, even in a case where the supply flow rate of the inert gas is increased, the exhaust flow rate can be increased in accordance with the supply flow rate to maintain the inside of the chamber at the chamber setting pressure, and therefore it is possible to supply a large amount of the inert gas to inside the chamber during an initial operation. As such, supplying a large amount of inert gas needed in order to replace the oxygen inside the chamber with the inert gas makes it possible to reduce the duration of time needed to fill the chamber with the inert gas during the initial operation.

The configuration may also be such that an upper limit pressure value and a lower limit pressure value are set for the chamber setting pressure, and the supply flow rate of the inert gas of the gas supply unit and the exhaust flow rate of the gas exhaust unit are adjusted so that the pressure inside the chamber is maintained between the upper limit pressure value and the lower limit pressure value.

According to this configuration, setting the upper limit pressure value and the lower limit pressure value as threshold values makes it possible to maintain the inside of the chamber at the chamber setting pressure with a simpler configuration.

The configuration may also be such that there is an initial operation mode, during which the supply flow rate of the gas supply unit and the exhaust flow rate of the gas exhaust unit are both increased and the pressure inside the chamber is maintained at a setting pressure value, and a normal operation mode, during which the supply flow rate of the gas supply unit and the exhaust flow rate of the gas exhaust unit are both reduced and the pressure inside the chamber is maintained at the setting pressure value, and the initial operation mode is switched to the normal operation mode in a case where the oxygen concentration inside the chamber reaches a setting value or lower.

According to this configuration, the oxygen concentration inside the chamber during the initial operation can be promptly lowered in a state where the chamber setting pressure has been maintained by the initial operation mode. Also, in a state where the chamber setting pressure has been maintained by the normal operation mode, it is possible to curb the amount of inert gas supplied and to curb wasteful consumption of the inert gas.

The configuration may also be such that the gas exhaust unit includes an exhaust piping communicatingly connected to the chamber, the exhaust piping includes a buffer unit the volume of which can be changed in accordance with a pressure fluctuation inside the piping, and a change in the volume of the buffer unit causes a rapid pressure fluctuation inside the piping to be absorbed.

According to this configuration, swelling of the volume of the buffer unit makes it possible to maintain the chamber setting pressure even in a case where the pressure inside the chamber is temporarily rapidly increased.

### Advantageous Effects of the Invention

According to the substrate processing system of the present invention, the pressure inside the chamber can be stably upheld, even when a variance occurs in the supply flow rate of the inert gas, and during the initial operation, it is possible to increase the supply flow rate of the inert gas and to reduce the duration of time needed to fill the chamber with the inert gas.

### BRIEF DESCRIPTION OF THE DRAWINGS

FIG. 1 is a schematic view illustrating the substrate processing system of the present invention;

FIG. 2 is a block diagram illustrating the configuration of a control system of the substrate processing system;

FIG. 3 is a drawing illustrating changes in pressure in a chamber; and

FIG. 4 is a flow chart illustrating the operation of the substrate processing system.

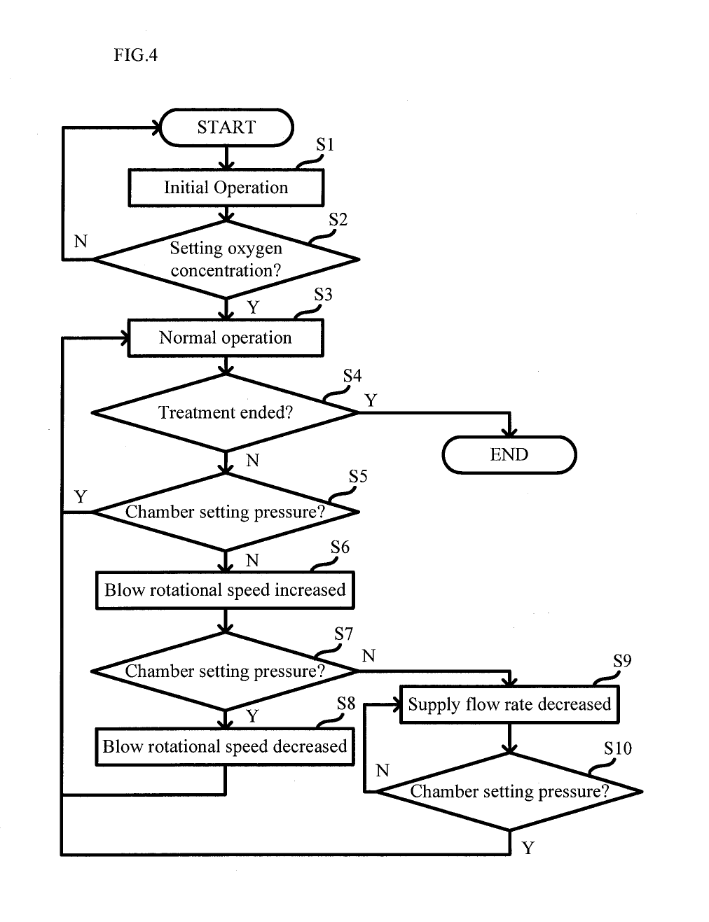

### DETAILED DESCRIPTION OF THE PREFERRED EMBODIMENTS

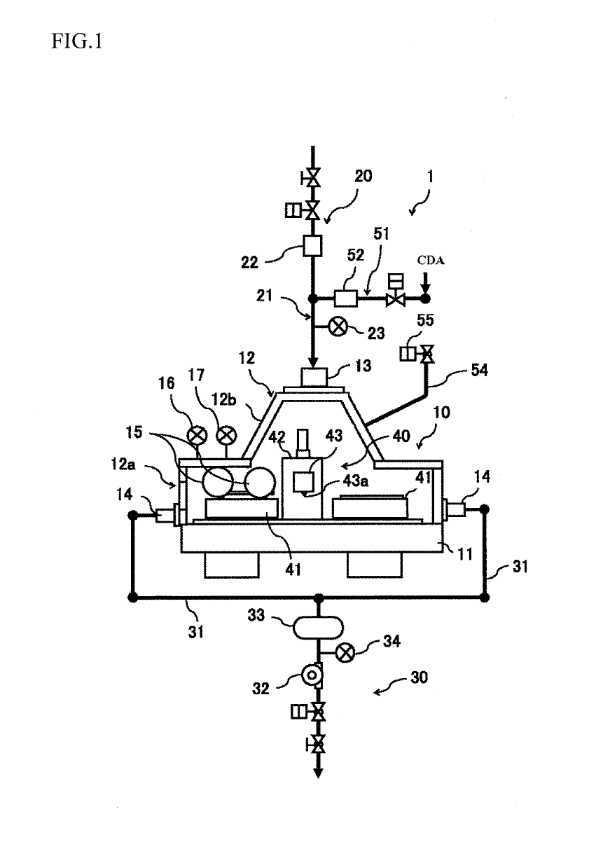

The following describes the substrate processing system of the present invention in greater detail. FIG. 1 is a drawing schematically illustrating a substrate processing system in one embodiment of the present invention.

As illustrated in FIG. 1, a substrate processing system 1 has a substrate processing apparatus 10, a gas supply unit 20, and a gas exhaust unit 30; an inert gas is supplied from the gas supply unit 20 to the substrate processing apparatus 10, and gas in the substrate processing apparatus 10 is discharged from the gas exhaust unit 30, whereby a predetermined processing is carried out on the substrate while the substrate is being maintained in a specific environment within the substrate processing apparatus 10.

The substrate processing apparatus 10 has a substrate processing section 40 on a base stand 11, and the substrate processing section 40 is accommodated within a chamber 12. In the present embodiment, the substrate processing section 40 is a coating apparatus, and a coated film made of a resist solution or the like is formed atop a substrate by the coating apparatus. The coating apparatus has a stage 41 atop which the substrate is placed, and a coating unit 42 for applying a coating solution; the coating solution is ejected from the coating unit 42, and a coated film of a uniform thickness is thereby formed atop the substrate. More specifically, the coating unit 42 is provided fixed to a substantially middle position on the base stand 11, and has a mouthpiece 43 having a slit nozzle 43a extending in one direction. That is, the coating solution supplied from the slit nozzle 43a is ejected from the slit nozzle 43 over the longitudinal direction. The stage 41 is provided so as to be able to move in one direction with respect to the coating unit 42, and the moving stage 41 crosses the slit nozzle 43a. As such, the coating solution is ejected from the slit nozzle 43a while the stage 41 is moving in the one direction in a state where the substrate has been placed atop the stage 41, whereby a coated film of uniform thickness is formed atop the substrate.

The substrate processing section 40 (in the present embodiment, the coating apparatus) is accommodated within the chamber 12. The chamber 12 has a shape that incorporates a cuboid 12a having a side surface part, and a convex crown 12b, where a middle portion at which the coating unit 42 is located is projected upward. The chamber 12 is formed by attaching a translucent acrylic plate to a metal frame, so that the substrate processing section 40 in the interior can be viewed from the exterior. Sealing members are provided to joint portions of the frame and between the frame and the acrylic plate, so that the substrate processing section 40 is sealed within the chamber 12. That is, the inert gas supplied from the gas supply unit 20 is collected in the chamber 12, so that oxygen and the like from the exterior can be prevented from entering into the chamber 12.

An interconnecting part 13 for interconnecting with the gas supply unit 20 is provided to the convex crown 12b of the chamber 12, and the inert gas is supplied from the gas supply unit 20 by way of the interconnecting part 13. An interconnecting part 14 for interconnecting with the gas exhaust unit 30 is provided to a side portion of the chamber 12, and the gas inside the chamber 12 is discharged from the gas exhaust unit 30 by way of the interconnecting part 14.

Also provided to a side surface portion of the chamber 12 is a glove box 15. The glove box 15 is intended for running maintenance of the substrate processing section 40 from the exterior of the chamber 12, and is formed by attaching rubber gloves to the chamber 12. More specifically, through holes are formed in two places in the side surface of the chamber 12, and rubber gloves are attached so as to close off the through holes. That is, the gloves are attached so that the fingertips of the rubber gloves extend toward the interior of the chamber 12. As such, at the time of maintenance such as wiping of the slit nozzle 43a, a worker can carry out the maintenance task without changing the gas environment (oxygen concentration) inside the chamber 12, by placing the hands in the rubber gloves and carrying out a predetermined maintenance processing on the substrate processing section 40.

An oxygen concentration meter 16 and pressure gauge 17 are attached to the chamber 12, so that the oxygen concentration and the pressure inside the chamber 12 can be measured. The oxygen concentration meter 16 and the pressure gauge 17 are electrically connected to a control device 90 (described below), and respective measurement results thereof are inputted to the control device 90.

The gas supply unit 20 is provided to the convex crown 12b of the chamber 12, and the inert gas, which is nitrogen or the like, is supplied from the gas supply unit 20 to inside the chamber 12. The gas supply unit 20 includes a supply piping 21 connected to the interconnecting part 13 of the convex crown 12b, and a regulator 22 provided to the supply piping 21. The supply piping 21 is connected to a compressed inert gas cylinder for nitrogen or the like, and by adjusting the regulator 22, it is possible to control the flow rate of the inert gas being supplied into the chamber 12. The regulator 22 is an electro-pneumatic regulator 22, and the open/closed state thereof is steplessly controlled by an electrical signal from the control device 90. As such, by using the control device 90, it is possible to increase or reduce the supply flow rate of the inert gas into the chamber 12.

A flow rate meter 23 is provided to the supply piping 21. The flow rate meter 23 is electrically connected to the control device 90, so that an exhaust flow rate measured thereby can be inputted to the control device 90.

A side surface part of the chamber 12 is coupled to the gas exhaust unit 30 via the interconnecting part 14, so that the gas inside the chamber 12 can be expelled to outside the chamber 12 by way of the gas exhaust unit 30. The gas exhaust unit 30 includes an exhaust piping 31 communicatingly connected to a side surface part of the chamber 12, and a blower 32 provided to the exhaust piping 31. In the example in FIG. 1, the exhaust piping 31 is coupled to two side surface parts, and the two exhaust pipings 31 meet and are coupled to a predetermined gas processing device (not shown). The blower 32 is provided to the meeting portion of the exhaust piping 31, so that actuating the blower 32 causes the gas inside the chamber 12 to be discharged by way of the exhaust piping 31. The rotational speed of the blower 32 is controlled by the control device 90, the rotational speed of the blower 32 being controlled steplessly by an electrical signal from the control device 90. Controlling the rotational speed of the blower 32 in this manner allows for the exhaust flow rate of the gas inside the chamber 12 to be adjusted.

The gas supply unit 20 and the gas exhaust unit 30 make it possible to control the pressure inside the chamber 12. That is, by reducing the exhaust flow rate of the gas exhaust unit 30 to be lower than the supply flow rate of the inert gas from the gas supply unit 20, it is possible to keep the pressure inside the chamber 12 high. In the present embodiment, adjusting the regulator 22 and the blower 32 as appropriate makes it possible to keep a somewhat higher pressure than the atmospheric pressure outside the chamber 12. This allows for the inside of the chamber 12 to be filled with the inert gas and prevents oxygen from entering in from outside the chamber 12.

A buffer unit 33 is also provided to the exhaust piping 31. The buffer unit 33 is for suppressing rapid pressure increases inside the chamber 12. This makes it possible to prevent the chamber 12 from being damaged by high pressures. More specifically, the buffer unit 33 is a bag-shaped member formed of an elastically deformable material, such as a rubber or resin, so as to expand elastically when the inside of the bag-shaped member reaches a predetermined pressure. That is, the buffer unit is formed of a material that expands at a pressure where the chamber 12 will not be damaged by the pressure increase. The buffer unit 33 has an inlet and outlet, and the exhaust piping 31 is connected to the inlet and to the outlet. This makes it possible to prevent the pressure inside the chamber 12 from suddenly increasing. That is, when the pressure inside the chamber 12 suddenly increases, the pressure inside the exhaust piping 31 also increase in association therewith, but when a equal or greater pressure than needed is applied to the buffer unit 33, the buffer unit expands and thereby lowers the pressure inside the exhaust piping 31, thus also lowering the pressure inside the chamber 12. This makes it possible to curb sudden pressure increases inside the chamber 12, and to prevent damage to the chamber 12.

A flow rate meter 34 is also provided to the exhaust piping 31. The flow rate meter 34 is electrically connected to the control device 90, so that an exhaust flow rate measured thereby can be inputted to the control device 90.

Also, separately coupled to the supply piping 21 is an air supply piping 51 for supplying air, so that air can be supplied to inside the chamber 12. More specifically, the air supply piping 51 is coupled to a compressed air cylinder, and a regulator 52 electrically connected to the control device 90 is provided to the air supply piping 51. By controlling an opening/closing operation of the regulator 52, it is possible to supply air to inside the chamber 12.

A vent piping 54 is connected to the chamber 12, so that the inert gas inside the chamber 12 can be discharged in a single burst. That is, the vent piping 54, which is connected to a vacuum pimp, is connected to the chamber 12, and a vent valve 55 by which the opening/closing operation is controlled is provided to the control device 90. When the vent valve 55 is released, the air inside chamber 12 is suctioned by the vacuum pump, and the gas inside the chamber 12 is discharged in a single burst. This makes it possible to prevent the inert gas from overflowing to outside the chamber 12 in a case where the substrate processing apparatus 10 suffers some form of failure, with the vent piping 54 and the air supply piping 51. More specifically, the vent valve 55 of the vent piping 54 is released, and the regulator 52, too, is placed in an open state, whereby the air inside the chamber 12 is discharged and air is supplied from the air supply piping 51. This makes it possible to prevent the inert gas from overflowing to outside the chamber 12, because the inert gas inside the chamber 12 is replaced by air in one burst.

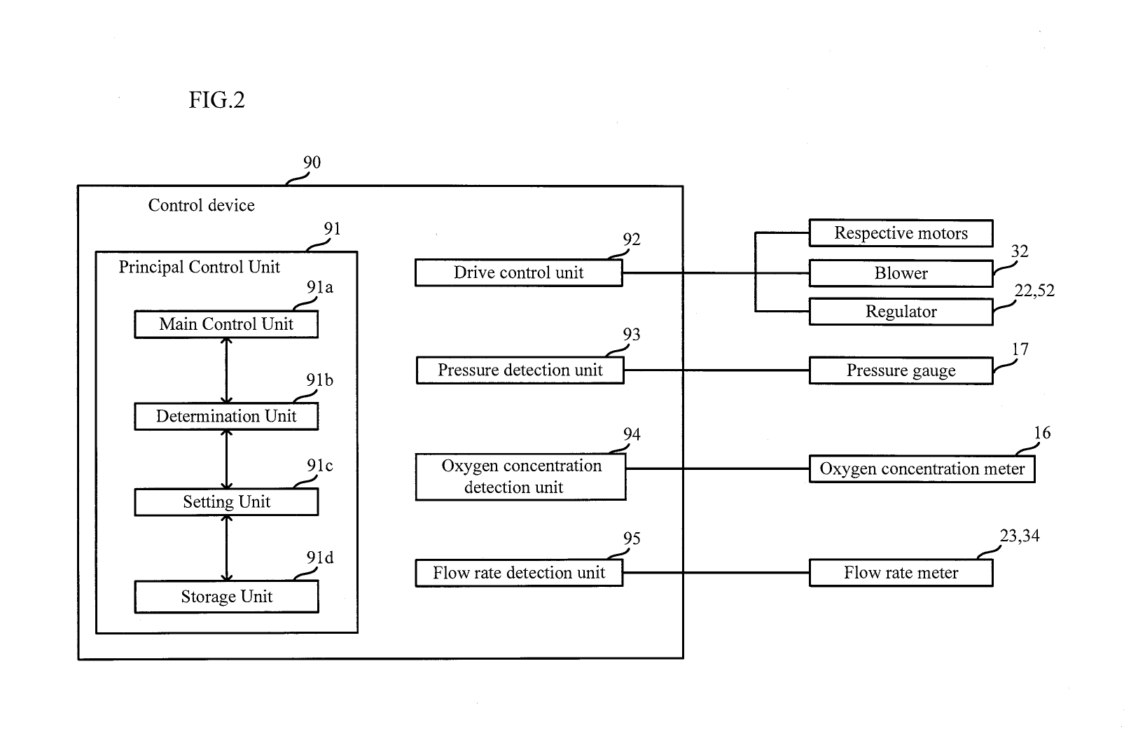

The following describes the configuration of the control system of the substrate processing apparatus 10, with reference to the block diagram illustrated in FIG. 2.

FIG. 2 is a block diagram illustrating the control system of the control device 90 provided to the substrate processing apparatus 10. As illustrated in FIG. 2, the control device 90, which has overall control of the drive of the variety of units described above, and the like, is provided to the substrate processing apparatus 10. The control device 90 has a principal control unit 91, a drive control unit 92, a pressure detection unit 93, an oxygen concentration detection unit 94, and a flow rate detection unit 95. The principal control unit 91 has a main control unit 91a, a determination unit 91b, a setting unit 91c, and a storage unit 91d.

The main control unit 91a is for driving and controlling a variety of drive equipment, such as the regulators 22, 52, and motors for each unit, via the drive control unit 92, as well as for carrying out a variety of computations needed for substrate processing operations, in order to execute a series of coating operations in accordance with a program that has been stored in advance. More specifically, the main control unit causes the coating solution to be ejected from the coating unit 42, and drives and controls the movement of the stage 41, in order to control the coating apparatus, which is the substrate processing section 40. Also controlled are the open/closed state of the regulator 22 and the rotational speed of the blower 32; the inside of the chamber 12 is set to a pressure somewhat higher than the outside of the chamber 12 (a chamber setting pressure).

The determination unit 91b determines whether or not the pressure and oxygen concentration inside the chamber 12 and the blower rotational speed are predetermined set values. For example, the question of whether or not the pressure inside the chamber 12 has reached a pressure that has been set (the chamber setting pressure) is determined. More specifically, the storage unit 91 d (described below) stores an upper limit value and a lower limit value for the chamber setting pressure, as threshold values, and the question of whether or not the pressure inside the chamber 12 falls within the range of the threshold values is determined. In a posited case where the upper limit value of the chamber setting pressure is exceeded, the rotational speed of the blower 32 is increased through the drive control unit 92, to increase the exhaust flow rate of the gas inside the chamber 12, whereby the pressure inside the chamber 12 is adjusted so as to fall within the threshold values. In a case where the pressure inside the chamber 12 does not fall within the threshold values even though the rotational speed of the blower 32 has been increased, the regulator 22 of the gas supply unit 20 is adjusted, whereby the supply flow rate is reduced and the pressure inside the chamber 12 is adjusted so as to fall within the threshold values. Similarly, in a case where the lower limit value of the chamber setting pressure is exceeded, the rotational speed of the blower 32 is lowered through the drive control unit 92. In a case where [the pressure inside the chamber 12] does not fall within the threshold values even though the rotational speed of the blower 32 has been increased, the regulator 22 of the gas supply unit 20 is adjusted, whereby the supply flow rate is reduced and the pressure inside the chamber 12 is adjusted so as to fall within the threshold values. In this manner, the pressure inside the chamber 12 is adjusted so as to reach the chamber setting pressure.

The determination unit 91b determines also the oxygen concentration of the chamber 12, and determines whether or not the oxygen concentration inside the chamber 12 is suitable for manufacturing a product. More specifically, the question of whether or not the oxygen concentration inside the chamber 12 has reached an oxygen concentration that is stored in the storage unit 91b is determined.

The setting unit 91c is for setting the chamber setting pressure, the degree of opening/closing of the regulator 22, and the rotational speed of the blower 32. In the substrate processing apparatus 10 of the present embodiment, two modes are prepared, depending on the operating environment of the apparatus. Namely, these are an initial operation mode and a normal operation mode. The initial operation mode is a mode that is used during the early stage of operation of the apparatus, and is a mode in which the primary purpose is to promptly lower the oxygen concentration inside the chamber 12. More specifically, the initial mode comprises placing the regulator 22 of the gas supply unit 20 into an appreciably more open state (lowering the constriction) and increasing the rotational speed of the blower 32, while also maintaining the upper limit value and lower limit value of the chamber setting pressure. The oxygen inside the chamber 12 is thereby replaced with the inert gas as soon as possible. The normal operation mode is a mode for operating the coating apparatus with a controlled amount of inert gas used, while also maintaining a state where the oxygen concentration inside the chamber 12 is at or below the set oxygen concentration. More specifically, in a state where the upper limit value and the lower limit value of the chamber setting pressure are maintained, the regulator 22 of the gas supply unit 20 is placed in a less open state (the constriction is increased) and the rotational speed of the blower 32 is set so as to be lower, in comparison to the initial operation mode. This makes it possible to curb the consumption of the inert gas while also maintaining the pressure inside the chamber 12 at the chamber setting pressure.

A degree of opening/closing of the regulator 22 and rotational speed of the blower 32 which correspond to the initial operation mode and the normal operation mode can be set by way of the drive control unit 92. The switch between the initial operation mode and the normal operation mode is carried out depending on the oxygen concentration inside the chamber 12. That is, in the state where the inside of the chamber 12 is air, the degree of opening/closing of the regulator 22 and the rotational speed of the blower are set to the initial operation mode, and the pressure inside the chamber 12 is maintained at the chamber setting pressure. When the inside of the chamber 12 reaches the set oxygen concentration that is stored in the storage unit 91d, the setting changes to the degree of opening/closing of the regulator 22 and the rotational speed of the blower of the normal operation mode, while the pressure inside the chamber 12 is maintained at the chamber setting pressure. This makes it possible to promptly replace the inside of the chamber 12 with the inert gas in the initial operation mode, and in the normal operation mode to curb the supply of unneeded inert gas, in a state where the inside of the chamber 12 is maintained at the chamber setting pressure.

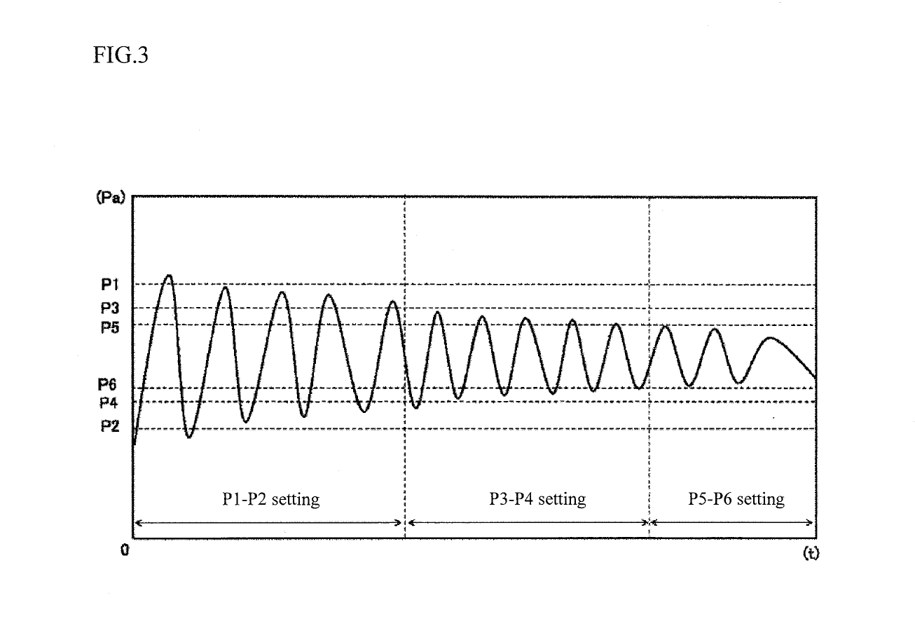

In the present embodiment, there is an auto-tuning function, and the chamber setting pressure is thereby adjusted so as to reach an optimal value. More specifically, as illustrated in FIG. 3, when the pressure inside the chamber 12 is maintained for a predetermined duration of time (a threshold value holding duration) within the threshold values of the chamber setting pressure that was initially set, then the threshold value region for the chamber setting pressure is re-set to an upper limit value and a lower limit value that are smaller. When the pressure inside the chamber 12 is maintained for the threshold value retention duration at the re-set threshold value region, then the threshold value region for the chamber setting pressure is again set to an upper limit value and a lower limit value that are smaller. By repeating this, it becomes possible to converge the chamber setting pressure at an optimal value and maintain same there, and it is possible to curb wasteful usage of inert gas during the normal operation mode.

The storage unit 91d is for storing a variety of various types of data, and for temporarily storing computation results and the like. More specifically, threshold value data, the threshold value retention duration, the set oxygen concentration, the degree of opening/closing of the regulator, the rotational speed of the blower, and the like for the chamber setting pressure in the initial operation mode and the normal operation mode are stored. A plurality of sets of upper limit values and lower limit values are prepared for the threshold value data for the chamber setting pressure; an upper limit value P1 and a lower limit value P2 are set as a largest threshold value region, an upper limit value P3 and a lower limit value P4 are set as an intermediate threshold value region, and, finally, an upper limit value P5 and a lower limit value P6 are set as a smallest threshold value region (see FIG. 3). The rotational speed of the blower is set as Ra in the initial operation mode and as Rb in the normal operation mode, the Ra of the initial operation mode being set to a greater value than the Rb of the normal operation mode. As regards the degree of opening/closing of the regulator 22, too, the amount of constriction in the initial operation mode is set so as to be smaller than the amount of constriction in the normal operation mode, and the supply flow rate in the initial operation mode is made to be greater than the supply flow rate in the normal operation mode.

The drive control unit 92 is for driving and controlling each of the motors, the drive equipment, and the like on the basis of a control signal from the principal control unit 91. More specifically, the degree of opening/closing of the regulator 22, the rotational speed of the blower 32, and the like are controlled.

The pressure detection unit 93 is for detecting the pressure inside the chamber 12. More specifically, the pressure inside the chamber 12 is detected by a signal that is inputted from the pressure gauge 17 attached to the chamber 12. The pressure thus detected is stored in the storage unit 91 d of the principal control unit 91.

The oxygen concentration detection unit 94 is for detecting the oxygen concentration inside the chamber 12. More specifically, the oxygen concentration inside the chamber 12 is detected by a signal that is inputted from the oxygen concentration meter 16 attached to the chamber 12. The oxygen concentration thus detected is stored in the storage unit 91d of the principal control unit 91.

The flow rate detection unit 95 is for detecting the gas flow rates inside the supply piping 21 and inside the exhaust piping 31. More specifically, the gas flow rates inside the supply piping 21 and inside the exhaust piping 31 are detected by a signal that is inputted from the flow rate meter 23 attached to the supply piping 21, and by a signal that is inputted from the flow rate meter 34 attached to the exhaust piping 31. The gas flow rates thus detected are stored in the storage unit 91d of the principal control unit 91.

The following describes the operation in the substrate processing apparatus 10, with reference to the flow chart.

Firstly, in step S1, initial operation is carried out (the initial operation mode). That is, because the chamber 12 is filled with air, the initial operation is carried out until the oxygen concentration inside the chamber 12 falls to the set oxygen concentration or below. More specifically, the chamber setting pressure is set to a combination where the threshold value region is greatest, i.e., to the upper limit value P1 and the lower limit value P2. The regulator 22 is set to the degree of opening/closing of the initial operation mode, and the rotational speed of the blower is set to Ra. The pressure inside the chamber 12 is converged to the chamber setting pressure while the supply flow rate of the inert gas and the exhaust flow rate of gas inside the chamber 12 both hold an equilibrium at high flow rate. That is, the supply flow rate of the inert gas is maintained at a state of somewhat surpassing the gas exhaust flow rate. Herein, in a posited case where the pressure inside the chamber 12 exceeds the upper limit value or lower limit value of the chamber setting pressure, the rotational speed of the blower is adjusted. That is, in a case where the upper limit value is exceeded, the rotational speed of the blower is somewhat increased and the pressure inside the chamber 12 is lowered. In a case where the lower limit value is exceeded, the rotational speed of the blower is lowered somewhat and the pressure inside the chamber 12 is increased. This makes it possible to promptly lower the oxygen concentration inside the chamber 12, by a large flow rate of inert gas being supplied to inside the chamber 12 while the pressure inside the chamber 12 is maintained at the chamber setting pressure.

The initial operation mode is carried out until the oxygen concentration inside the chamber 12 reaches the set oxygen concentration (the direction of NO in step S2). When the oxygen concentration inside the chamber 12 does reach the set oxygen concentration, the flow proceeds towards YES from step S2, and step S3 causes normal operation to be carried out (the normal operation mode).

More specifically, the chamber setting pressure is set to the upper limit value P1 and the lower limit value P2, which are the combination where the threshold value region is largest; also, the regulator 22 is set to the degree of opening/closing of the normal operation mode, and the rotational speed of the blower is set to Rb. As a result, because the degree of opening/closing of the normal operation mode has a greater constriction than that of the degree of opening/closing of the initial operation mode, the supply flow rate is suppressed. Also, because the rotational speed Rb of the blower of the normal operation mode is lower than the rotational speed Ra of the blower of the initial operation mode, the exhaust flow rate is also suppressed. That is, in the normal operation mode the supper flow rate and the exhaust flow rate hold a balance with a lesser flow rate in comparison to the initial operation mode, and the pressure inside the chamber 12 is converged on the chamber setting pressure. The normal operation mode thereby has a suppressed amount of inert gas consumed in comparison to the initial operation mode.

Herein, in a posited case where the pressure inside the chamber 12 exceeds the upper limit value or the lower limit value of the chamber setting pressure, the rotational speed of the blower is adjusted. That is, in a case where the upper limit value is exceeded, the rotational speed of the blower is somewhat increased and the pressure inside the chamber 12 is lowered. In a case where the lower limit value is exceeded, the rotational speed of the blower is lowered somewhat and the pressure inside the chamber 12 is increased. Thus, in a case where the pressure inside the chamber 12 falls within the threshold values for the chamber setting pressure for a predetermined duration of time, the threshold values for the chamber setting pressure are altered to a threshold value region of a narrower range. That is, the upper limit value P1 is altered from P1 to P3, and the lower limit value is altered from P2 to P4. In a case where the upper limit value or the lower limit value is exceeded, similarly with respect to before, the rotational speed of the blower is increased and the pressure inside the chamber 12 is adjusted so as to fall within the threshold value region. By repeating this, the values are ultimately set to the upper limit value P5 and the lower limit value P6, which are the narrowest threshold value region, and the chamber setting pressure is maintained within this range. The chamber setting pressure is thereby adjusted so as to reach an optimal value (the auto-tuning feature).

Next, in step S4, a determination is made as to whether or not to stop the apparatus. More specifically, in a case where the processing for the substrate is ended and the substrate is removed, or in a case where the substrate processing apparatus 10 is forcibly stopped, the flow proceeds in the direction of YES in step S4, and the operation of the substrate processing apparatus 10 is ended. In a case where the processing for the substrate is continuously carried out, the flow proceeds in the direction of NO in step S4, and the operation of the substrate processing apparatus 10 is continued.

Next, in step S5, a determination is made as to whether or not the pressure inside the chamber 12 is being held at the chamber setting pressure. That is, in a case where the pressure inside the chamber 12 is being held at the chamber setting pressure, the flow proceeds in YES in step S5, and the normal operation mode is continuously executed. In a posited case where the [pressure inside the chamber 12] falls out of the range of the chamber setting pressure, such as when maintenance work is being carried out, then the flow proceeds in the direction of NO in step S5, and the rotational speed of the blower 32 is increased. More specifically, the task of wiping the mouthpiece 43 is included as a maintenance task of the present embodiment. The wiping task comprises the task of wiping the mouthpiece 43 while the hands are placed in the gloves of the glove box 15, for which purpose the pressure inside the chamber 12 is elevated by an amount commensurate with the hands being placed into the gloves, and the upper limit value of the chamber setting pressure will be exceeded. Thus, when an attempt is made to cause the pressure inside the chamber 12 to rapidly exceed the upper limit value of the chamber setting value, the buffer unit 33 then expands, and an attempt is made to alleviate the elevated pressure. In a case where the upper limit value of the chamber setting pressure is nevertheless exceeded, then the chamber setting pressure is determined not to have been held, and the flow proceeds in the direction of NO in step S5; in step S6, the rotational speed of the blower is increased.

When, in step S6, the rotational speed of the blower is increased, the pressure inside the chamber 12 is lowered. Then, in step S7, a determination is made as to whether or not the pressure inside the chamber 12 falls within the chamber setting pressure. That is, the pressure inside the chamber 12, upon falling within the range of the threshold values (the upper limit value and the lower limit value) of the chamber setting pressure, is determined to have reached the chamber setting pressure, and the flow proceeds in the direction of YES in step S7; in step S8, the rotational speed of the blower is reduced. The normal operation mode is then again executed, and the chamber setting pressure is adjusted by the auto-tuning function described above so as to reach an optimal value.

In step S7, when the pressure inside the chamber 12 is determined not to fall within the chamber setting pressure, the flow proceeds in the direction of NO in step S7; in step S9, the amount of inert gas supplied is suppressed. More specifically, the constriction of the regulator 22 of the gas supply unit 20 is increased and the degree of opening/closing is adjusted. In step S10, a determination is made as to whether or not the pressure inside the chamber 12 falls within the chamber setting pressure. That is, a determination is made as to whether or not the pressure inside the chamber 12 falls within the range of the threshold values (the upper limit value and the lower limit value) of the chamber setting pressure, and in a case where the pressure inside the chamber 12 does not fall within the range of the threshold values, then the flow proceeds in the direction of NO in step S10, and the regulator 22 is adjusted. In a case where the pressure inside the chamber 12 is determined to fall within the range of the threshold values, then in step S10 the flow proceeds in the direction of YES, and the normal operation mode is executed; the chamber setting pressure is adjusted by the auto-tuning feature described above so as to reach an optimal value.

According to the substrate processing system 1 in the embodiment described above, the supply flow rate of the inert gas of the gas supply unit 20 and the exhaust flow rate of the gas exhaust unit 30 are adjusted, and therefore the pressure inside the chamber 12 can be maintained stable at the chamber setting pressure. That is, even though a variance may occur in the supply flow rate of the inert gas, the exhaust flow rate is adjusted in accordance with the supply flow rate, whereby the inside of the chamber 12 is maintained at the chamber setting pressure, and whereby also it is possible to increase the supply flow rate of the inert gas at the time of initial operation and reduce the duration of time needed to fill the inside of the chamber 12 with the inert gas.

The embodiment above describes an example where the oxygen concentration is measured as a condition for operating the substrate processing apparatus 10, but the dew point temperature may also be measured in combination with the oxygen concentration, with both the oxygen concentration and the dew point temperature serving as conditions for operating the substrate processing apparatus 10. More specifically, the configuration may be such that a dew point temperature meter is installed in the chamber 12, and a switch is made from the initial operation mode to the normal operation mode depending on data obtained by the dew point temperature meter and on data obtained from the oxygen concentration meter 16.

The embodiment above describes an example where the blower 32 is provided to the gas exhaust unit 30, but a vacuum pump or a process pump may be used. Even then, the gas inside the chamber 12 can still be sufficiently discharged.

1. A substrate processing system, comprising:
a substrate processing device performing predetermined treatment on a substrate;
a chamber housing the substrate processing device in a sealed state;
a gas supply unit supplying an inert gas to the chamber; and
a gas exhaust unit exhausting the gas supplied in the chamber, thereby a supply flow rate of the gas supply unit and an exhaust flow rate of the gas exhaust unit being controlled on the basis of a chamber pressure in order to make a chamber setting-pressure higher than the pressure outside the chamber.

2. The substrate processing system according to claim 1, wherein
an upper limit pressure value and a lower limit pressure value are set for the chamber setting pressure,
an upper limit pressure value and a lower pressure value are set for the chamber setting pressure, and
the supply flow rate the gas supply unit and the exhaust flow rate of the gas exhaust unit are controlled in order to keep the chamber pressure being adjusted between the upper limit pressure value and the lower limit pressure value.

3. The substrate processing system according to claim 1, further comprising:
an initial operation mode having the supply flow rate and the exhaust flow rate while the chamber pressure being kept at the chamber setting value; and a normal operation mode having a reduced supply flow rate and reduced exhaust flow rate lower than those of the initial operation mode while the chamber pressure being kept at the chamber setting value, wherein the initial operation mode is switched to the normal operation mode when the oxygen concentration inside the chamber is reduced to reaches a setting value or lower.

4. The substrate processing system according to claim 1, wherein:
the gas exhaust unit includes exhaust piping coupled with the chamber, the exhaust piping having a buffer capable of volume-change in accordance with a pressure fluctuation inside the piping, thereby absorbing by a volume change of the buffer a rapid pressure fluctuation inside the chamber.

5. The substrate processing system according to claim 2, wherein
the gas exhaust unit includes exhaust piping coupled with the chamber, the exhaust piping having a buffer capable of volume-change in accordance with a pressure fluctuation inside the piping, thereby absorbing by a volume change of the buffer a rapid pressure fluctuation inside the chamber.

6. The substrate processing system according to claim 3, wherein
the gas exhaust unit includes exhaust piping coupled with the chamber, the exhaust piping having a buffer capable of volume-change in accordance with a pressure fluctuation inside the piping, thereby absorbing by a volume change of the buffer a rapid pressure fluctuation inside the chamber.
